(19) United States
(12) Patent Application Publication
(10) Pub. No.: US 2017/0062959 A1
(43) Pub. Date: Mar. 2, 2017

(54) CIRCUIT BOARD PASSAGE TERMINAL

(71) Applicant: Phoenix Contact GmbH & Co. KG, Blomberg (DE)

(72) Inventors: Andreas Schrader, Delbrueck (DE); Ingo Werner, Detmold (DE)

(21) Appl. No.: 15/123,260

(22) PCT Filed: Mar. 12, 2015
(86) PCT No.: PCT/EP2015/055127

§ 371 Date: Sep. 2, 2016

(30) Foreign Application Priority Data
Mar. 14, 2014 (DE) 10 2014 103 562.3

(51) Int. Cl. H01R 12/72; H01R 4/48; H01R 12/51; H05K 1/11; H01R 13/74

(52) U.S. Cl. CPC H01R 12/722; H05K 1/117; H01R 13/74; H01R 12/515; H01R 4/4827

(57) ABSTRACT

An arrangement of a circuit board passage terminal on a circuit board includes a housing having a conductor receiving opening for receiving an electrical conductor, and an operating opening for fixing or releasing the electrical conductor upon insertion into the conductor receiving opening; a contact element for soldering and electrically contacting the circuit board passage terminal to a soldering face of the circuit board; and a flange component having an outer face and a mounting face, the mounting face of the flange component resting on the soldering face of the circuit board when the circuit board passage terminal is arranged in a recess in the circuit board.

### CROSS-REFERENCE TO PRIOR APPLICATIONS

This application is a U.S. National Phase application under 35 U.S.C. §371 of International Application No. PCT/EP2015/055127, filed on Mar. 12, 2015, and claims benefit to German Patent Application No. DE 10 2014 103 562.3, filed on Mar. 14, 2014. The International Application was published in German on Sep. 17, 2015 as WO 2015/136020 A1 under PCT Article 21(2).

### FIELD

The invention relates to an arrangement of a circuit board passage terminal on a circuit board, to the use of a circuit board passage terminal for arrangement on a circuit board, and to a method for arranging a circuit board passage terminal on a circuit board.

### BACKGROUND

The arrangement of circuit board passage terminals on circuit boards is known, in principle, from the field of connection technology. Arrangements of this type generally comprise a circuit board having an upper face, a lower face and an opening for receiving a circuit board passage terminal. The circuit board passage terminal generally comprises a housing having a base strip for receiving a plug-in connector, plug-in contacts for electrical connection to the circuit board, and a mounting device for mounting on and connection to the circuit board.

The circuit board passage terminal is generally guided through the opening in the circuit board from the upper face and mounted on the mounting device. The base strip for receiving the plug-in connector is subsequently arranged on the lower face of the circuit board.

Because the known circuit board passage terminals comprise a base strip for receiving a plug-in connector, the overall height of the circuit board passage terminals is correspondingly large. In addition, the base strip for receiving the plug-in connector is arranged in a direction perpendicular to the plane of the circuit board, resulting in cables of the plug-in connector likewise extending in a direction perpendicular to the plane of the circuit board, further increasing the overall height of the connection.

### SUMMARY

An arrangement includes a circuit board passage terminal and a circuit board. The circuit board includes a soldering face and a component face, and a recess for receiving the circuit board passage terminal being arranged in the circuit board. The circuit board passage terminal includes a housing having a conductor receiving opening for receiving an electrical conductor, and an operating opening for fixing or releasing the electrical conductor upon insertion into the conductor receiving opening; a contact element for soldering and electrically contacting the circuit board passage terminal to the soldering face of the circuit board; and a flange component having an outer face and a mounting face, the mounting face of the flange component resting on the soldering face of the circuit board when the circuit board passage terminal is arranged in the recess in the circuit board.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 is a three-dimensional view of an arrangement of two circuit board passage terminals on a circuit board according to a preferred embodiment of the invention,

FIG. 2 is a further three-dimensional view of the arrangement of two circuit board passage terminals on the circuit board according to the preferred embodiment of the invention, and

FIG. 3 is a side view of the arrangement of two circuit board passage terminals on the circuit board according to the preferred embodiment of the invention.

### DETAILED DESCRIPTION

In an embodiment, the invention provides an arrangement of a circuit board passage terminal on a circuit board, the circuit board comprising a soldering face and a component face, and a recess for receiving the circuit board passage terminal being arranged in the circuit board, the circuit board passage terminal comprising a housing having a conductor receiving opening for receiving an electrical conductor and an operating opening for fixing or releasing an electrical conductor inserted into the conductor receiving opening, comprising a contact element for soldering and electrically contacting the circuit board passage terminal to the soldering face of the circuit board, and comprising a flange component having an outer and a mounting face, and the mounting face of the flange component resting on the soldering face of the circuit board when the circuit board passage terminal is arranged in the recess in the circuit board.

It is thus an aspect of the invention that the circuit board passage terminal comprises a housing having a conductor receiving opening for receiving an electrical conductor and having an operating opening for fixing or releasing an electrical conductor inserted into the conductor receiving opening. In this way, individual electrical conductors can be inserted into the conductor receiving opening in the circuit board passage terminal and electrically contacted, making it possible to reduce the component height of the circuit board passage terminal.

A further preferred development of the invention involves the circuit board passage terminal being a PCB terminal block. In this way, the electrical conductor can be inserted into the conductor receiving opening and electrically contacted in a simple manner.

In principle, the recess in the circuit board may be arranged in the plane of the circuit board. In this case, the circuit board passage terminal is plugged into the recess in a direction perpendicular to the plane of the circuit board and is arranged on the circuit board. However, a preferred development of the invention provides that the circuit board has an edge region and the recess is arranged in the edge region of the circuit board. In this way, the circuit board passage terminal can be plugged into the recess in a direction perpendicular to the plane of the circuit board or pushed into the recess in the circuit board in a direction parallel to the plane of the circuit board.

A further preferred development of the invention provides that an outer wall of the housing of the circuit board passage terminal is arranged in a plane parallel to the plane of the mounting face of the flange component.

Furthermore, a preferred development of the invention involves the circuit board passage terminal being arranged on the circuit board in such a way that the mounting face of the flange component rests on the soldering face of the circuit board and at least one sub-region of the outer wall of the housing abuts the component face of the circuit board. In this way, an arrangement of the circuit board passage terminal on the circuit board is provided in which the circuit board passage terminal is positively fixed to the circuit board in a direction perpendicular to the plane of the circuit board. Mechanical forces which act on the circuit board passage terminal in a direction perpendicular to the plane of the circuit board are thus transmitted to the circuit board either via the flange component or via the sub-region of the outer wall abutting the component face.

A further advantageous development of the invention provides that the flange component is arranged on the housing of the circuit board passage terminal in such a way that the outer wall of the housing and the outer face of the flange component form a plane. In this way, the component height of the circuit board passage terminal on the soldering face of the circuit board is determined by the height of the flange component. Thus, depending on the height of the flange component, the shadow cast by the circuit board passage terminal on the soldering face can be reduced, this being potentially advantageous in particular for the arrangement of the circuit board passage terminal in LED applications.

A further advantageous development of the invention provides that the flange component is an armature which consists of a solderable material and is pressed into the housing of the circuit board passage terminal. In this connection, a further preferred development provides that the armature is soldered to the circuit board on the soldering face thereof. In this way, the circuit board passage terminal is integrally joined to the circuit board. By way of the integral joint, mechanical forces acting on the arrangement, such as the mechanical forces acting on the arrangement when the electrical conductor is plugged into and contacted with the circuit board passage terminal, can be absorbed.

Furthermore, the armature consisting of a solderable material preferably has a flange height of between 0.5 mm and 3 mm. If the armature is arranged on the housing of the circuit board passage terminal in such a way that the outer face of the armature forms a plane with the outer wall of the housing, the component height of the circuit board passage terminal can be reduced on the soldering face of the circuit board and the shadow cast can thus be reduced.

As an alternative to the armature consisting of a solderable material, a further preferred development of the invention provides that the flange component is formed integrally with the housing of the circuit board passage terminal. In this way, the housing of the circuit board passage terminal can be manufactured at low expense.

A further preferred development of the invention provides that the contact element is formed as a soldering tag, the soldering tag preferably being arranged on the outer wall of the housing and the soldering tag being soldered to the soldering face of the circuit board for electrical contact therewith. In this way, the circuit board passage terminal can preferably be formed as an SMD-solderable circuit board passage terminal and be arranged on the circuit board.

However, a particularly advantageous development of the invention provides that the contact element is formed as a soldering pin, the soldering pin being arranged on the outer wall of the housing in a direction perpendicular to the plane of the outer wall, a slit being formed in the recess in the circuit board, and the circuit board passage terminal being arranged in the recess in the circuit board in such a way that the soldering pin engages in the slit and is soldered to the soldering face of the circuit board. In this way, a circuit board passage terminal is provided which can be pushed into the recess in the circuit board in a direction parallel to the plane of the circuit board, and the soldering pin is passed through the circuit board.

A further advantageous development of the invention involves the conductor receiving opening being arranged in such a way that an electrical conductor can be inserted into the conductor receiving opening on the component face of the circuit board. In this way, the component height of the circuit board passage terminal on the soldering face can be reduced.

Furthermore, a particularly preferred development of the invention provides that the conductor receiving opening is arranged in such a way that an electrical conductor can be inserted into the conductor receiving opening in a direction parallel to the plane of the circuit board. In this way, the mechanical forces which act on the arrangement when an electrical conductor is inserted into the conductor receiving opening act in a direction parallel to the plane of the circuit board.

In addition, in this way, an arrangement is provided which makes a small overall height of the circuit board passage terminal possible, since the conductor to be contacted with the circuit board passage terminal is guided in a direction parallel to the plane of the circuit board and can also be inserted into the conductor receiving opening in a direction parallel to the plane of the circuit board. Moreover, in this way users are given further freedoms in the configuration of the contour of a housing receiving the circuit board.

The operating opening for fixing or soldering an electrical conductor inserted into the conductor receiving opening may be arranged at various points on the housing of the circuit board passage terminal. However, a preferred development of the invention provides that the operating opening is arranged in a direction parallel to the conductor receiving opening or in a direction perpendicular to the conductor receiving opening. If the operating opening is arranged in a direction parallel to the conductor receiving opening, the mechanical forces which act on the arrangement when an electrical conductor is fixed in or released from the conductor receiving opening act in a direction parallel to the plane of the circuit board.

If the operating opening is arranged in a direction perpendicular to the conductor receiving opening, a preferred development of the invention involves the operating opening being arranged in the outer wall of the housing of the circuit board passage terminal. In this way, the mechanical forces which act on the arrangement when an electrical conductor is fixed in or released from the conductor receiving opening act in a direction perpendicular to the plane of the circuit board, compressive forces being transmitted to the circuit board via the flange connection.

A further preferred development of the invention involves the circuit board passage terminal comprising a plurality of conductor receiving openings, a plurality of operating openings and a plurality of contact elements.

Furthermore, an advantageous development of the invention involves the circuit board passage terminal comprising a plurality of flange components. In this way, the connection of the circuit board passage terminal to the circuit board can be increased.

In addition, the invention relates to the use of a circuit board passage terminal for arrangement on a circuit board, the circuit board comprising a soldering face and a component face, and a recess for receiving the circuit board passage terminal being arranged in the circuit board, the circuit board passage terminal comprising a housing having a conductor receiving opening for receiving an electrical conductor and an operating opening for fixing or releasing an electrical conductor inserted into the conductor receiving opening, comprising a contact element for soldering and electrically contacting the circuit board passage terminal to the soldering face of the circuit board, and comprising a flange component having an outer face and a mounting face, and the mounting face of the flange component being fixed to the soldering face of the circuit board when the circuit board passage terminal is arranged in the recess in the circuit board.

In addition, the invention provides a method for arranging a circuit board passage terminal on a circuit board, the circuit board comprising a soldering face and a component face, and a recess for receiving the circuit board passage terminal being arranged in the circuit board, the circuit board passage terminal comprising a housing having a conductor receiving opening for receiving an electrical conductor and an operating opening for fixing or releasing an electrical conductor inserted into the conductor receiving opening, comprising a contact element for soldering and electrically contacting the circuit board passage terminal to the soldering face of the circuit board, and comprising a flange component having an outer face and a mounting face, and the circuit board passage terminal being plugged into the recess in the circuit board in a direction perpendicular to the plane of the circuit board, the mounting face of the flange component resting on the soldering face of the circuit board, or the circuit board passage terminal being pushed into the recess in the circuit board in a direction parallel to the plane of the circuit board, the mounting face of the flange component resting on the soldering face of the circuit board.

The description of the arrangement of a circuit board passage terminal on a circuit board and in particular the developments of the invention are also applicable to the use of a circuit board passage terminal for arrangement on a circuit board and to the method for arranging a circuit board passage terminal on a circuit board.

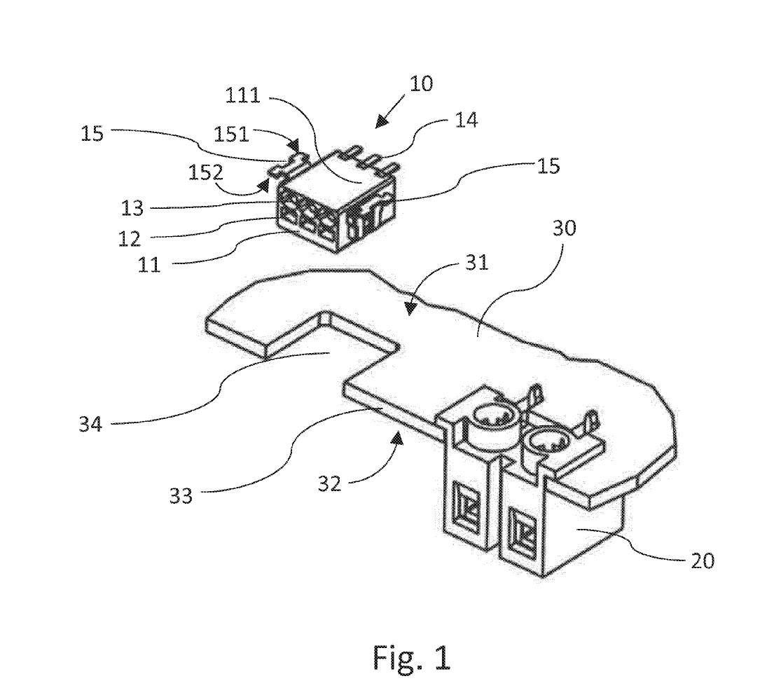

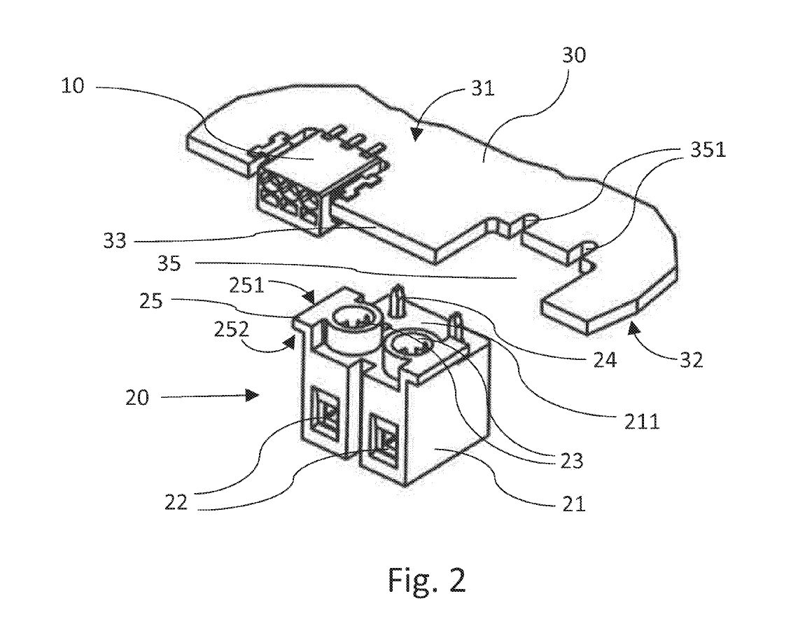

FIGS. 1 and 2 show the arrangement of a first circuit board passage terminal 10 and a second circuit board passage terminal 20 on a circuit board 30. The arrangement of the first circuit board passage terminal 10 on the circuit board 30 is disclosed with reference to FIG. 1. The arrangement of the second circuit board passage terminal 20 on the circuit board 30 is discussed in greater detail with reference to FIG. 2.

As can be seen from FIG. 1, the circuit board 30 comprises a soldering face 31 and a component face 32. In addition, the circuit board 30 comprises an edge region 33 and a first recess 34 arranged in the edge region 33 for receiving the first circuit board passage terminal 10.

The first circuit board passage terminal 10 comprises a housing 11 having three conductor receiving openings 12, arranged side by side, each for receiving an electrical conductor. Three operating openings 13, arranged side by side, each for fixing or releasing the electrical conductor inserted into the corresponding conductor receiving opening 12, are arranged parallel to the conductor receiving openings 12. Corresponding to the number of conductor receiving openings 12, the first circuit board passage terminal 10 comprises three contact elements 14 for soldering and electrically contacting the first circuit board passage terminal 10 to the soldering face 31 of the circuit board 30.

The first circuit board passage terminal 10 further comprises two flange components 15 having an outer face 151 and a mounting face 152, the flange components 15 each being formed as an armature consisting of a solderable material and being pressed into the housing 11 of the first circuit board passage terminal 10.

For arranging the first circuit board passage terminal 10 on the circuit board 30, the first circuit board passage terminal 10 may be plugged into the first recess 34 in the circuit board 30 in a direction perpendicular to the plane of the circuit board 30, in such a way that the mounting faces 152 of the flange components 15 subsequently rest on the soldering face 31 of the circuit board 30. Alternatively, however, the first circuit board passage terminal 10 may also be pushed into the first recess 34 in the circuit board 30 in a direction parallel to the plane of the circuit board 30, in such a way that the mounting faces 152 of the flange components 15 rest on the soldering face 31 of the circuit board 30.

Because the flange components 15 are formed as an armature consisting of a solderable material, the first circuit board passage terminal can be integrally joined to the soldering face 31 of the circuit board by way of a soldered connection.

It can further be seen that the housing 11 of the first circuit board soldered connection 10 comprises an outer wall 111 and the outer faces 151 of the flange component 15 form a plane together with the outer wall 111. In this way, the component height of the first circuit board passage terminal 10 on the soldering face 31 of the circuit board 30 is determined by the height of the flange component 15. Depending on the height of the flange component 15, the shadow cast by the first circuit board passage terminal 10 on the soldering face 31 can thus be reduced, and this may be advantageous in particular for the use of the first circuit board passage terminal 10 in LED applications.

It can additionally be seen from FIG. 1 that the conductor receiving openings 12 are arranged in such a way that an electrical conductor can be inserted into the conductor receiving opening 12 in a direction parallel to the plane of the circuit board 30. Thus, the mechanical forces which act on the arrangement when an electrical conductor is inserted into the conductor receiving opening 12 act in a direction parallel to the plane of the circuit board 30.

The mechanical forces which act on the arrangement when an electrical conductor is fixed in or released from the conductor receiving opening 12 likewise act in a direction parallel to the plane of the circuit board 30, since the operating openings 13 are arranged in a direction parallel to the direction of the conductor receiving openings 12.

In FIG. 2, the circuit board 30 known from FIG. 1 is shown having a second recess 35 for receiving the second circuit board passage terminal 20. The second circuit board passage terminal 20 comprises a housing 21 having two conductor receiving openings 22, arranged side by side, each for receiving an electrical conductor, and two operating openings 23, each for fixing or soldering the electrical conductor inserted into the corresponding conductor receiving opening 22, the operating openings 23 being arranged in a direction perpendicular to the direction of the conductor receiving openings 22. It can further be seen that the operating openings 23 are arranged in the outer wall 211 of the housing 21.

The second circuit board passage terminal 20 additionally comprises two contact elements 24 on the outer wall 211, each formed as a soldering pin. Furthermore, two flange components 25 are arranged on the housing 21 of the second circuit board passage terminal 20, the flange components 25 each comprising an outer face 251 and a mounting face 252. The flange components 25 are formed integrally with the housing 21 of the second circuit board passage terminal 20.

For arranging the second circuit board passage terminal 20 on the circuit board 30, the second circuit board passage terminal 20 is pushed into the second recess 35 in a direction parallel to the plane of the circuit board 30, the mounting face 252 of the associated flange component 25 resting on the soldering face 31 of the circuit board 30, and the region of the outer wall 211 in which the contact elements 24 are arranged abutting the component face 32 of the circuit board. In addition, each contact element 24 engages in a slit 351 in the circuit board 30. In this way, the second circuit board passage terminal 20 is positively fixed to the circuit board 30 in a direction perpendicular to the plane of the circuit board 30. By soldering the contact elements 24 to the soldering face 31 of the circuit board 30, the second circuit board passage terminal 20 is electrically contacted with the circuit board 30.

It can further be seen that the conductor receiving openings 22 are arranged in such a way that an electrical conductor can be inserted into the conductor receiving opening 22 in a direction parallel to the plane of the circuit board 30. In this way, the mechanical forces which act on the arrangement when an electrical conductor is inserted into the conductor receiving opening 22 act in a direction parallel to the plane of the circuit board 30.

Because the operating openings 23 are arranged in a direction perpendicular to the direction of the conductor receiving openings 22, the mechanical forces which act on the conductor receiving opening 22 when an electrical conductor is fixed in or released from the conductor receiving opening act in a direction perpendicular to the plane of the circuit board 30, compressive forces being transmitted to the circuit board 30 via the flange connection 15.

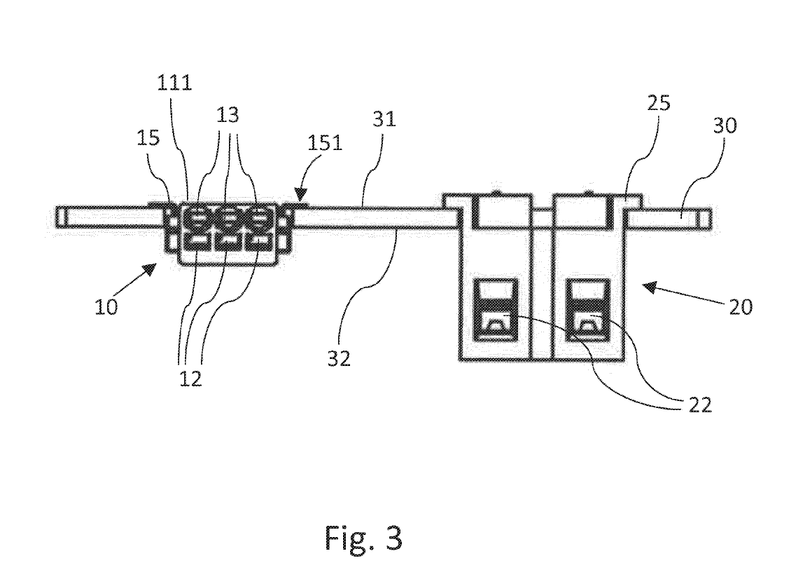

FIG. 3 shows the arrangement of the first circuit board passage terminal 10 on the circuit board 30 and the arrangement of the second circuit board passage terminal 20 on the circuit board 30. It can further be seen that the conductor receiving openings 12, 22 are arranged in such a way that an electrical conductor can be inserted into the corresponding conductor receiving opening 12, 22 on the component face 32 of the circuit board 30. The component height of the first circuit board passage terminal 10 or the second circuit board passage terminal 20 on the soldering face 31 can thus be reduced.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

10 First circuit board passage terminal
11 Housing
111 Outer wall
12 Conductor receiving opening
13 Operating opening
14 Contact elements
15 Flange component
151 Outer face
152 Mounting face
20 Second circuit board passage terminal
21 Housing
211 Outer wall
22 Conductor receiving opening
23 Operating opening
24 Contact elements
25 Flange component
251 Outer face
252 Mounting face
30 Circuit board
31 Soldering face
32 Component face
33 Edge region
34 First recess
35 Second recess
351 Slit

1: An arrangement comprising:
a circuit board passage terminal; and
a circuit board,
the circuit board comprising a soldering face and a component face,
and a recess for receiving the circuit board passage terminal being arranged in the circuit board,
the circuit board passage terminal comprising:
a housing having a conductor receiving opening configured to receive an electrical conductor, and an operating opening configured to fix or release the electrical conductor upon insertion into the conductor receiving opening;
a contact element configured to solder and electrically contact the circuit board passage terminal to the soldering face of the circuit board; and
a flange component having an outer face and a mounting face,
the mounting face of the flange component resting on the soldering face of the circuit board when the circuit board passage terminal is arranged in the recess in the circuit board.

2. The arrangement according to claim 1, wherein the circuit board has an edge region and the recess is arranged in the edge region.

3. The arrangement according to claim 1, wherein an outer wall of the housing of the circuit board passage terminal is arranged in a plane parallel to a plane of the mounting face of the flange component.

4. The arrangement according to claim 3, wherein the circuit board passage terminal is arranged on the circuit board such that the mounting face of the flange component rests on the soldering face of the circuit board and at least one sub-region of the outer wall of the housing abuts the component face of the circuit board.

5. The arrangement according to claim 4, wherein the contact element comprises a soldering pin, the soldering pin being arranged on the outer wall of the housing in a direction perpendicular to the plane of the outer wall, a slit being formed in the recess in the circuit board, and the circuit board passage terminal being arranged in the recess in the circuit board such that the soldering pin engages in the slit and is soldered to the soldering face of the circuit board.

6. The arrangement according to claim 1, wherein the conductor receiving opening is arranged such that an electrical conductor can be inserted into the conductor receiving opening on the component face of the circuit board.

7. The arrangement according to claim 1, wherein the conductor receiving opening is arranged such that an electrical conductor can be inserted into the conductor receiving opening in a direction parallel to a plane of the circuit board.

8. The arrangement according to claim 1, wherein the operating opening is arranged in a direction parallel to the conductor receiving opening or in a direction perpendicular to the conductor receiving opening.

9. (canceled)

10. A method for arranging a circuit board passage terminal on a circuit board,
the circuit board comprising a soldering face and a component face,
and a recess configured to receive the circuit board passage terminal being arranged in the circuit board;
the circuit board passage terminal comprising:
a housing having a conductor receiving opening configured to receive an electrical conductor and an operating opening configured for fixing or releasing an electrical conductor inserted into the conductor receiving opening;
a contact element configured to solder and electrically contact the circuit board passage terminal to the soldering face of the circuit board; and
a flange component having an outer face and a mounting face,
the method comprising at least one of:
plugging the circuit board passage terminal into the recess in the circuit board in a direction perpendicular to a plane of the circuit board, the mounting face of the flange component resting on the soldering face of the circuit board, or
pushing the circuit hoard passage terminal into the recess in the circuit board in a direction parallel to the plane of the circuit board, the mounting face of the flange component resting on the soldering face of the circuit board.
